(19) United States
(12) Patent Application Publication
(10) Pub. No.: US 2025/0183032 A1
(43) Pub. Date: Jun. 5, 2025

(54) FILM FORMING METHOD AND FILM FORMING APPARATUS

(71) Applicant: Tokyo Electron Limited, Tokyo (JP)

(72) Inventors: Shuji AZUMO, Yamanashi (JP); Yumiko KAWANO, Yamanashi (JP); Takashi FUSE, Yamanashi (JP); Shinichi IKE, Gyeonggi-do (KR); Tomohiro NAKAGAWA, Yamanashi (JP)

(21) Appl. No.: 18/845,623

(22) PCT Filed: Mar. 6, 2023
(86) PCT No.: PCT/JP2023/008247

§ 371 Date: Sep. 10, 2024

(30) Foreign Application Priority Data
Mar. 17, 2022 (JP) 2022-042331

(51) Int. Cl. H01L 21/02; C23C 16/04; C23C 16/455; C23C 16/52

(52) U.S. Cl. CPC H01L 21/02299; C23C 16/042; C23C 16/4554; C23C 16/52; H01L 21/02118; H01L 21/0228

(57) ABSTRACT

A film forming method includes (A) to (E) as follows. (A) A substrate having a first film and a second film formed of a material different from a material of the first film in different regions of a surface of the substrate is prepared. (B) A fluorine-containing self-assembled monolayer, which inhibits formation of a target film, is selectively formed on a surface of the second film. (C) After (B), a precursor gas of the target film is supplied. (D) After (C), the target film is formed on a surface of the first film by supplying a reaction gas that reacts with the precursor gas to the surface of the substrate. (E) After (C) and before or after (D), the self-assembled monolayer is removed by a plasmarized gas. A first cycle including (B), (C), (D), and (E) once each is repeatedly performed multiple times.

### TECHNICAL FIELD

The present disclosure relates to a film forming method and a film forming apparatus.

### BACKGROUND

Patent Document 1 discloses a film forming method in which a self-assembled monolayer (SAM) is used to inhibit a target film (third film) from being formed on a portion of a substrate surface and the target film (third film) is formed on another portion of the substrate surface. In Patent Document 1, an organic compound containing fluorine is used as a precursor of the SAM. After the target film is formed, the SAM is excited by irradiating the target film with at least any of ions or active species and active species containing fluorine and carbon is generated. In addition, the active species containing fluorine and carbon react with a side portion of the target film adjacent to the SAM. As a result, the side portion of the target film becomes a volatile compound and is removed.

### PRIOR ART DOCUMENT

### [Patent Document]

Patent Document 1: Japanese Patent Laid-open Publication No. 2021-44534

### SUMMARY

One aspect of the present disclosure provides a technique capable of selectively forming a target film in a desired region even when blocking performance of a SAM which inhibits formation of the target film is insufficient.

A film forming method according to one aspect of the present disclosure includes (A) to (E) as follows. (A) A substrate having a first film and a second film made of a material different from a material of the first film in different regions of a surface of the substrate is prepared. (B) A fluorine-containing self-assembled monolayer, which inhibits formation of a target film, is selectively formed on a surface of the second film with respect to a surface of the first film. (C) After (B), a precursor gas of the target film is supplied to the surface of the substrate. (D) After (C), the target film is selectively formed on the surface of the first film with respect to the surface of the second film, by supplying a reaction gas that reacts with the precursor gas to the surface of the substrate. (E) After (C) and before or after (D), the self-assembled monolayer is removed by supplying a plasmarized gas to the surface of the substrate. A first cycle including (B), (C), (D), and (E) once each is repeatedly performed multiple times.

According to one aspect of the present disclosure, it is possible to selectively form a target film in a desired region even when blocking performance of an SAM which inhibits formation of the target film is insufficient.

### BRIEF DESCRIPTION OF DRAWINGS

FIG. 1 is a flowchart illustrating a film forming method according to an embodiment.

FIG. 2A is a diagram illustrating a first example of step S101.

FIG. 2B is a diagram illustrating a first example of step S102.

FIG. 2C is a diagram illustrating a first example of step S103.

FIG. 2D is a diagram illustrating a first example of step S104.

FIG. 3A is a diagram illustrating a first example of step S105.

FIG. 3B is a diagram illustrating a first example of step S106.

FIG. 3C is a diagram illustrating a first example of step S107.

FIG. 4 is a flowchart illustrating an example of a subroutine of step S104.

FIG. 5 is a flowchart illustrating a first modification of FIG. 1.

FIG. 6 is a flowchart illustrating a second modification of FIG. 1.

FIG. 7A is a diagram illustrating a second example of step S101.

FIG. 7B is a diagram illustrating a second example of step S102.

FIG. 7C is a diagram illustrating a second example of step S103.

FIG. 7D is a diagram illustrating a second example of step S104.

FIG. 8A is a diagram illustrating a second example of step S105.

FIG. 8B is a diagram illustrating a second example of step S106.

FIG. 8C is a diagram illustrating a second example of step S107.

FIG. 9A is a diagram illustrating a third example of step S101.

FIG. 9B is a diagram illustrating a third example of step S102.

FIG. 9C is a diagram illustrating a third example of step S103.

FIG. 9D is a diagram illustrating a third example of step S104.

FIG. 10A is a diagram illustrating a third example of step S105.

FIG. 10B is a diagram illustrating a third example of step S106.

FIG. 10C is a diagram illustrating a third example of step S107.

FIG. 11 is a plan view illustrating a film forming apparatus according to an embodiment.

FIG. 12 is a cross-sectional view illustrating an example of a first processor in FIG. 11.

### DETAILED DESCRIPTION

Hereinafter, embodiments of the present disclosure will be described with reference to the accompanying drawings. In each drawing, the same or corresponding components are denoted by the same reference numerals, and the description thereof may be omitted.

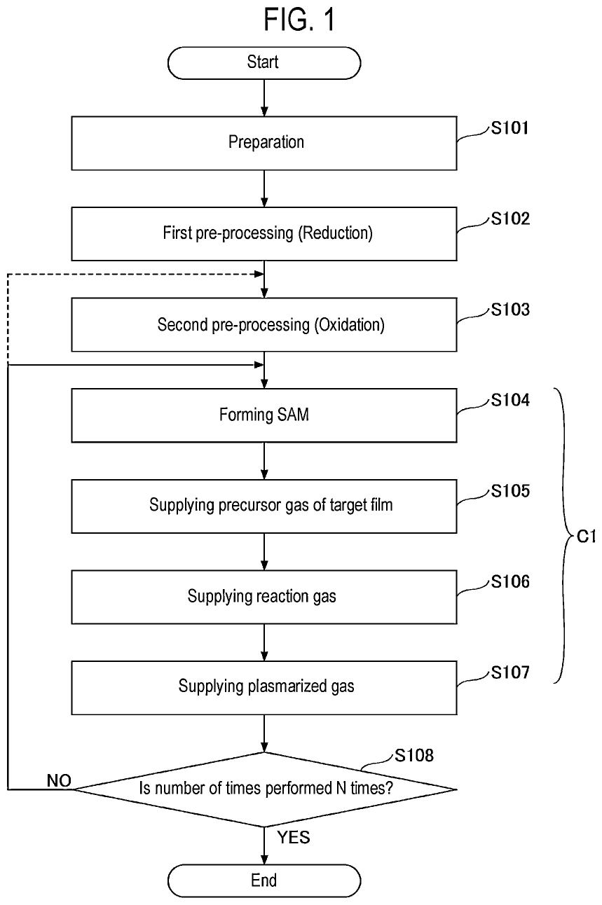

A film forming method according to an embodiment will now be described with reference to FIGS. 1 to 3C. The film forming method has, for example, steps S101 to S108 illustrated in FIG. 1. The film forming method may have at least step S101 and steps S104 to S108. For example, the film forming method may not have steps S102 and S103. In addition, the film forming method may have steps other than steps S101 to S108 illustrated in FIG. 1.

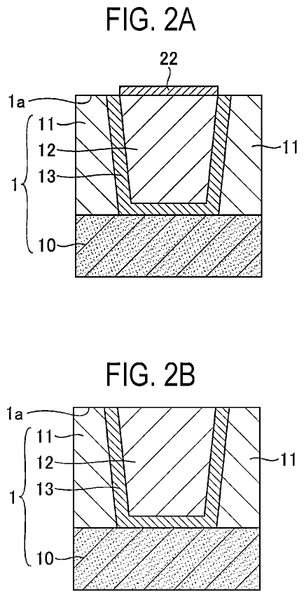

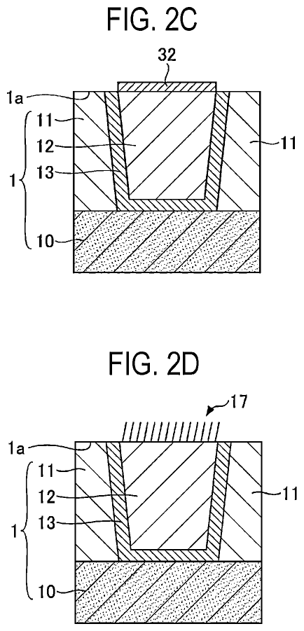

Step S101 in FIG. 1 includes preparing a substrate 1 as illustrated in FIG. 2A. The substrate 1 has a base substrate 10. The base substrate 10 is, for example, a silicon wafer, a compound semiconductor wafer, or a glass substrate. The substrate 1 has an insulating film 11 and a conductive film 12 in different regions of a substrate surface 1a. The substrate surface 1a is, for example, an upper surface of the substrate 1. The insulating film 11 and the conductive film 12 are formed on the base substrate 10. Another functional film may be formed between the base substrate 10 and the insulating film 11 or between the base substrate 10 and the conductive film 12. The insulating film 11 is an example of a first film, and the conductive film 12 is an example of a second film. Materials of the first film and the second film are not particularly limited. The first film may be a conductive film, and the second film may be an insulating film.

The insulating film 11 is, for example, an interlayer insulating film. The interlayer insulating film may be a low dielectric constant (low-k) film. The insulating film 11 is not particularly limited and is, for example, a SiO film, a SiN film, a SiC film, a SiOC film, a SiCN film, a SiON film, or a SiOCN film. Here, the SiO film means a film containing silicon (Si) and oxygen (O). An atomic ratio of Si to O in the SiO film is usually 1:2 but is not limited to 1:2. Similarly, each of the SiN film, the SiC film, the SiOC film, the SiCN film, the SiON film, and the SiOCN film also means a film containing corresponding elements and is not limited to a stoichiometric ratio. The insulating film 11 has a recess on the substrate surface 1a. The recess is a trench, a contact hole, or a via hole.

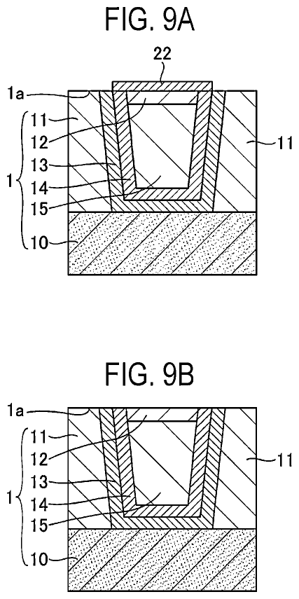

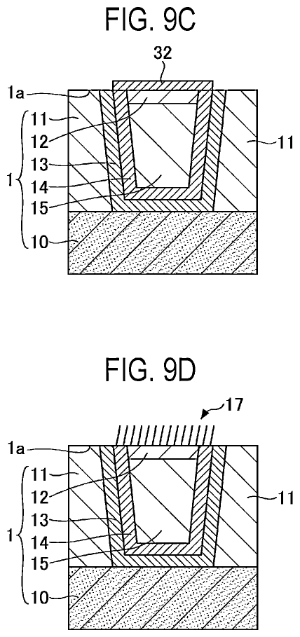

The conductive film 12 is filled, for example, in the recess of the insulating film 11. The conductive film 12 is, for example, a metal film. The metal film is, for example, a Cu film, a Co film, a Ru film, a W film, or a Mo film. In addition, the conductive film 12 may be a cap film. In other words, as illustrated in FIG. 9A, a second conductive film 15 may be embedded in the recess of the insulating film 11, and the second conductive film 15 may be covered by the conductive film 12. The second conductive film 15 is formed of a metal different from that of the conductive film 12.

The substrate 1 may further have a third film on the substrate surface 1a. The third film is, for example, a barrier film 13. The barrier film 13 is formed between the insulating film 11 and the conductive film 12, and suppresses metal diffusion from the conductive film 12 to the insulating film 11. The barrier film 13 is not particularly limited and is, for example, a TaN film or a TiN film. Here, the TaN film means a film containing tantalum (Ta) and nitrogen (N). Ab atomic ratio of Ta to N in the TaN film is usually 1:1 but is not limited to 1:1. Similarly, the TiN film means a film containing corresponding elements and is not limited to a stoichiometric ratio.

Table 1 summarizes specific examples of the insulating film 11, the conductive film 12, and the barrier film 13.

TABLE 1

| Insulating Film | Conductive Film | Barrier Film |
|---|---|---|
| SiO Film | Cu Film | TaN Film |
| SiN Film | Co Film | TiN Film |
| SiOC Film | Ru Film | |
| SiON Film | W Film | |
| SiOCN Film | | |
| SiCN Film | | |

In addition, a combination of the insulating film 11, the conductive film 12, and the barrier film 13 is not particularly limited.

Step S102 in FIG. 1 includes cleaning the substrate surface 1a as illustrated in FIG. 2B. A contaminant 22 (see FIG. 2A) present on the substrate surface 1a can be removed. The contaminant 22 includes, for example, at least one of a metal oxide or an organic material. The metal oxide is, for example, an oxide formed by a reaction between the conductive film 12 and the atmosphere and is a so-called natural oxide film. The organic material is, for example, a deposit containing carbon and adheres during processing the substrate 1.

For example, step S102 includes supplying a cleaning gas to the substrate surface 1a. The cleaning gas may be plasmarized in order to improve removal efficiency of the contaminant 22. The cleaning gas includes, for example, a reducing gas such as H₂ gas. The reducing gas removes the contaminant 22. Step S102 is a dry process but may also be a wet process.

An example of processing conditions for step S102 is as follows.
Flow rate of H₂ gas: 200 sccm to 3,000 sccm
Power supply frequency for plasma generation: 400 kHz to 40 MHz
Power for plasma generation: 50 W to 1,000 W
Processing time: 1 second to 60 seconds
Processing temperature: 50 degrees C. to 300 degrees C.
Processing pressure: 10 Pa to 7,000 Pa

Step S103 in FIG. 1 includes forming an oxide film 32 by oxidizing a surface of the conductive film 12 as illustrated in FIG. 2C. For example, step S103 includes forming the oxide film 32 by supplying an oxygen-containing gas to the substrate surface 1a. The oxygen-containing gas includes at least one selected from the group consisting of O₂ gas, O₃ gas, H₂O gas, NO gas, NO₂ gas, and N₂O gas. Step S103 is a dry process but may be a wet process.

Since removing the contaminant 22 is completed before step S103, the oxide film 32 having a desired film thickness and desired film quality is obtained by step S103. The film quality includes a surface state of a film. Unlike a natural oxide film, the film thickness and film quality of the oxide film 32 can be controlled according to a raw material gas and film formation conditions. By forming the oxide film 32 having a desired film thickness and desired film quality, a dense self-assembled monolayer (SAM) can be formed on the surface of the conductive film 12 in step S104 described later.

An example of processing conditions for step S103 is as follows.
Flow rate of O₂ gas: 100 sccm to 2,000 sccm
Processing time: 10 seconds to 300 seconds
Processing temperature: 100 degrees C. to 250 degrees C.
Processing pressure: 200 Pa to 1,200 Pa

Step S104 in FIG. 1 includes selectively forming a SAM 17 containing fluorine on the surface of the conductive film 12 with respect to the surface of the insulating film 11, as illustrated in FIG. 2D. The SAM 17 is formed by supplying a gas of an organic compound into a processing container that accommodates the substrate 1. The organic compound is a precursor of the SAM 17.

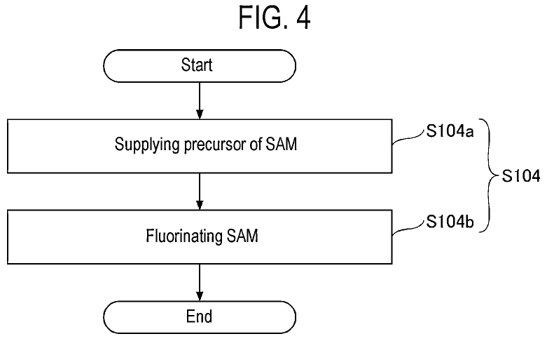

For example, the SAM 17 containing fluorine is formed by using an organic compound containing fluorine as the precursor of SAM 17. Further, as illustrated in FIG. 4, supplying an organic compound without containing fluorine to the substrate surface 1a as the precursor of the SAM 17 (step S104a), and fluorinating the SAM 17 (step S104b) may be performed.

The use of the organic compound without containing fluorine as the precursor of the SAM 17 contributes to environmental conservation. In addition, compared with an organic compound that contains fluorine, the organic compound without containing fluorine hardly remains in the processing container accommodating the substrate 1, so that stability (reproducibility) of a processing quality of the substrate 1 can be increased.

The organic compound includes, for example, a first functional group, and a second functional group provided at one end of the first functional group. The first functional group is a hydrocarbon group or a group obtained by replacing at least a part of hydrogen of the hydrocarbon group with fluorine. The first functional group may be linear. The first functional group may be an alkyl group or a group obtained by replacing at least a part of the alkyl group with fluorine. The first functional group may have an unsaturated bond such as a double bond. The second functional group is chemically adsorbed to the surface of the conductive film 12.

The organic compound as the precursor of the SAM 17 is not particularly limited and is, for example, a thiol-based compound. The thiol-based compound is represented by a general formula of “R—SH.” R is, for example, a hydrocarbon group or a group obtained by replacing at least a part of hydrogen of the hydrocarbon group with fluorine and corresponds to the first functional group. The SH group corresponds to the second functional group. A specific example of the thiol-based compound is CF₃(CF₂)ₓCF₂SH (where X is an integer of 1 to 16) and CH₃(CH₂)ₓCH₂SH (where X is an integer of 1 to 16).

The thiol-based compound is chemically adsorbed more easily to the surface of the conductive film 12 than to the surface of the insulating film 11. Therefore, the SAM 17 is selectively formed on the surface of the conductive film 12 with respect to the surface of the insulating film 11. The SAM 17 is not formed on the surface of the insulating film 11 and is hardly formed even on a surface of the barrier film 13.

When the oxide film 32 is formed before the SAM 17 is formed, compared to a case in which the oxide film 32 is not formed, a density of the SAM 17 can be improved, thereby improving blocking performance of the SAM 17 in step S105 described later. Since the thiol-based compound is chemically adsorbed while reducing the oxide film 32, the oxide film 32 may not remain after step S104 (see FIGS. 2D, 7D, and 9D).

In addition, the precursor of the SAM 17 is not limited to the thiol-based compound. For example, the precursor of the SAM 17 may be an organic silane-based compound, a phosphonic acid-based compound, or an isocyanate-based compound. The organic silane-based compound is represented by a general formula of “R—Si(OCH₃)₃” or “R—SiCl₃.” The phosphonic acid-based compound is represented by a general formula of “R—P(═O)(OH)₂.” The isocyanate-based compound is represented by a general formula of “R—N═C=O.” In these general formulas, R is, for example, a hydrocarbon group or a group obtained by replacing at least a part of hydrogen of the hydrocarbon group with fluorine.

An example of processing conditions for step S104 is as follows.
Gas flow rate of organic compound: 50 sccm to 500 sccm
Processing time: 10 seconds to 1,800 seconds
Processing temperature: 100 degrees C. to 350 degrees C.
Processing pressure: 100 Pa to 14,000 Pa

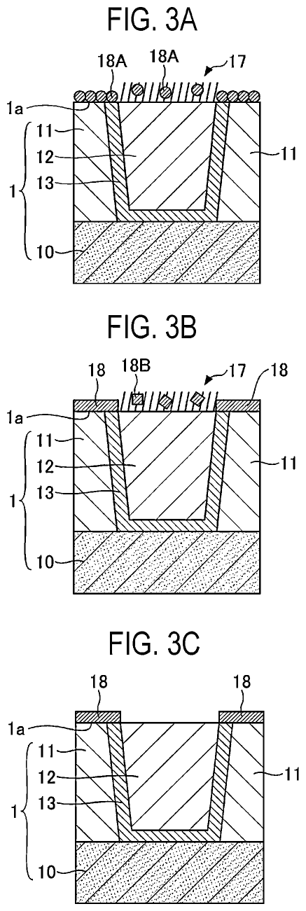

Steps S105 and S106 in FIG. 1 includes forming a target film 18 on the surface of the insulating film 11 while inhibiting the target film 18 from being formed on the surface of the conductive film 12 by using the SAM 17, as illustrated in FIGS. 3A and 3B. The target film 18 is, for example, an insulating film. In addition, since the blocking performance of the SAM 17 is not perfect, a nucleus 18B of the target film 18 may be deposited on the SAM 17.

The target film 18 is not particularly limited and is, for example, an AlO film, a SiO film, a SiN film, a ZrO film, or a HfO film. Here, the AlO film means a film containing aluminum (Al) and oxygen (O). An atomic ratio of Al to O in the AlO film is usually 2:3 but is not limited to 2:3. Similarly, each of the SiO film, SiN film, ZrO film, and HfO film also means a film containing corresponding elements and is not limited to a stoichiometric ratio.

The target film 18 is formed by, for example, an atomic layer deposition (ALD) method. When the target film 18 is formed by the ALD method, a precursor gas of the target film 18 and a reaction gas are alternately supplied to the substrate surface 1a. The precursor gas of the target film 18 contains, for example, a metal element or a metalloid element.

The reaction gas forms the target film 18 by reacting with the precursor gas of the target film 18. The reaction gas is, for example, an oxidizing gas or a nitriding gas. The oxidizing gas forms an oxide film of the metal element or the metalloid element contained in the precursor gas. The nitriding gas forms a nitride film of the metal element or the metalloid element contained in the precursor gas.

Additionally, the reaction gas may be a reducing gas. The reducing gas forms a metal film or a semiconductor film by using the metal element or the metalloid element contained in the precursor gas. The target film 18 may be a metal film or a semiconductor film.

Step S105 in FIG. 1 includes supplying the precursor gas of the target film 18 to the substrate surface 1a. As illustrated in FIG. 3A, since the SAM 17 is formed on the surface of the conductive film 12, a precursor gas 18A is selectively adsorbed to the surface of the insulating film 11.

An example of processing conditions for step S105 is shown below. In addition, in the processing conditions below, trimethylaluminum (TMA) gas is a precursor gas of an AlO film.
Flow rate of TMA gas: 1 sccm to 300 sccm (desirably 50 sccm)
Processing time: 0.1 to 2 seconds
Processing temperature: 100 degrees C. to 250 degrees C.
Processing pressure: 133 Pa to 1,200 Pa

Step S106 in FIG. 1 includes supplying the reaction gas to the substrate surface 1a after step S105 (supplying the precursor gas). The reaction gas forms the target film 18 by reacting with the precursor gas 18A of the target film 18, as illustrated in FIG. 3B.

An example of processing conditions for step S106 is shown below. In addition, in the processing conditions below, H₂O gas reacts with the TMA gas to form the AlO film.
Flow rate of H₂O gas: 10 sccm to 200 sccm
Processing time: 0.1 seconds to 2 seconds
Processing temperature: 100 degrees C. to 250 degrees C.
Processing pressure: 133 Pa to 1,200 Pa

As illustrated in FIGS. 3A and 3B, although the SAM 17 inhibits formation of the target film 18, the blocking performance of the SAM 17 is not perfect, and thus the nucleus 18B of the target film 18 may be deposited even on the SAM 17. When steps S105 and S106 are repeatedly performed multiple times without intervening step S107 therebetween, which will be described later, the nucleus 18B of the target film 18 grows, and the target film 18 is formed even on the conductive film 12 as well.

Step S107 in FIG. 1 includes removing the SAM 17, as illustrated in FIG. 3C, by supplying a plasmarized gas to the substrate surface 1a after step S105. A gas to be plasmarized is not particularly limited, but includes, for example, at least one selected from the group consisting of H₂ gas, NH₃ gas, N₂ gas, and Ar gas. The plasmarized gas excites the SAM 17 to decompose and remove the SAM 17.

When the SAM 17 contains fluorine and carbon, by the excitation of the SAM 17, active species containing fluorine and carbon are generated. The active species generated from the SAM 17 react with the nucleus 18B of the target film 18 deposited on the SAM 17. As a result, the nucleus 18B becomes a volatile compound and is removed. Before the nucleus 18B grows, the nucleus 18B can be removed from the conductive film 12. The target film 18 remains on the insulating film 11. The reason is because active species are generated only in a vicinity of the SAM 17.

An example of processing conditions for step S107 is shown below.
Flow rate of H₂ gas: 200 sccm to 3,000 sccm
Power supply frequency for plasma generation: 400 kHz to 40 MHz
Power for plasma generation: 50 W to 1,000 W
Processing time: 1 second to 60 seconds
Processing temperature: 50 degrees C. to 300 degrees C.
Processing pressure: 10 Pa to 7,000 Pa

Step S108 in FIG. 1 includes checking whether a first cycle C1 has been performed a set number of times (N times). The first cycle C1 includes step S104 (forming the SAM), step S105 (supplying the precursor gas), step S106 (supplying the reaction gas), and step S107 (supplying the plasmarized gas) once each. The first cycle C1 may also include step S103 (oxidizing the conductive film).

The first cycle C1 is repeatedly performed multiple times, for example, in the same processing container. The first cycle C1 is repeatedly performed multiple times by supplying various gases in a desired order into the same processing container. Between adjacent steps, there may be a step of discharging the various gases remaining in the processing container by supplying an inert gas such as argon gas into the processing container.

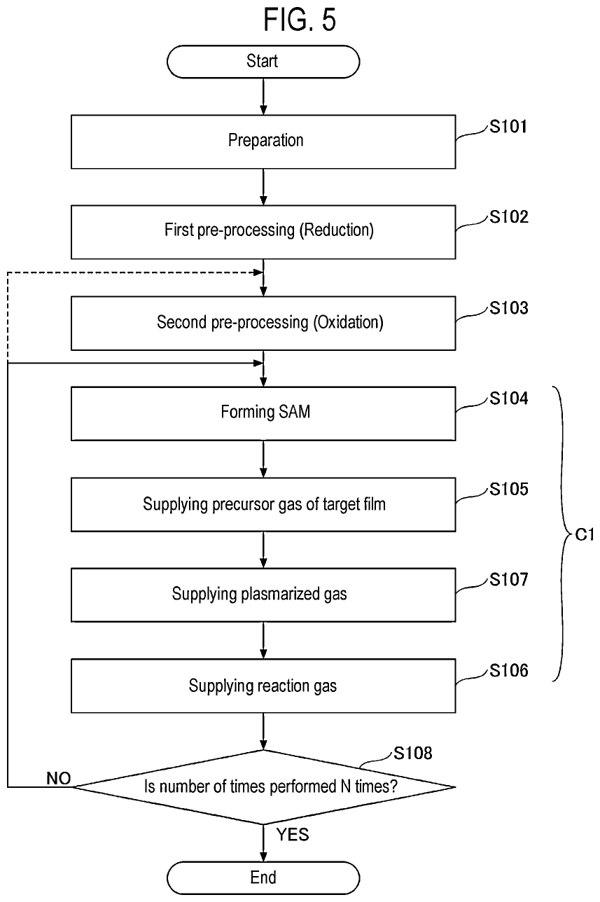

As long as the first cycle C1 includes step S107 after step S105, step S107 may be included after step S106 as illustrated in FIG. 1, or before step S106 as illustrated in FIG. 5.

Even in the latter case (in the case of the method of FIG. 5), the plasmarized gas excites the SAM 17 in step S107 as in the former case (in the case of the method of FIG. 1), so that active species containing fluorine and carbon are generated. The active species are generated only in the vicinity of the SAM 17. The active species generated from the SAM 17 react with the precursor gas 18A adsorbed to the SAM 17, thereby removing the precursor gas 18A from above the conductive film 12. Since the active species are generated in the vicinity of the SAM 17, the precursor gas 18A remains as being adsorbed on the insulating film 11. In subsequent step S106, the reaction gas reacts with the precursor gas 18A to selectively form the target film 18 on the surface of the insulating film 11. In the case of the method of FIG. 5, step S106 may include supplying a plasmarized reaction gas to the substrate surface 1a. The reaction gas may or may not be plasmarized according to a type of the gas used and conditions used.

The set number of times (N times) in step S108 is set according to a target film thickness of the target film 18 and is, for example, 20 times to 80 times. A thickness of the target film 18 formed in every first cycle C1 is a 1-atom level to a several-atom level and is less than 1 nm. When the number of times of performing the first cycle C1 has not reached the set number of times (N times) (“NO” in step S108), since the film thickness of the target film 18 has not reached the target film thickness, the first cycle C1 is performed again. On the other hand, when the number of times of performing the first cycle C1 has reached the set number of times (N times) (“YES” in step S108), since the film thickness of the target film 18 has reached the target film thickness, the processing ends.

According to the present embodiment, the first cycle C1 is repeatedly performed multiple times. The first cycle C1 includes step S104 (forming the SAM), step S105 (supplying the precursor gas), step S106 (supplying the reaction gas), and step S107 (supplying the plasmarized gas) once each. While depositing the target film 18 little by little, the nucleus 18B of the target film 18 deposited on the SAM 17 can be removed before the nucleus 18B grows. In addition, the order of steps S106 and S107 may be reversed (see FIG. 5). When step S106 is performed after step S107, the precursor gas 18A adsorbed to the SAM 17 can be removed before the nucleus 18B is formed.

Accordingly, even when the blocking performance of the SAM 17 is insufficient, the target film 18 can be selectively formed in a desired region. This effect is noticeably achieved when the conductive film 12 is a Ru film. The reason is because when the conductive film 12 is a Ru film, compared to a case in which the conductive film 12 is a Cu film, the density of the SAM 17 formed on the conductive film 12 easily decreases and the blocking performance of the SAM 17 easily decreases.

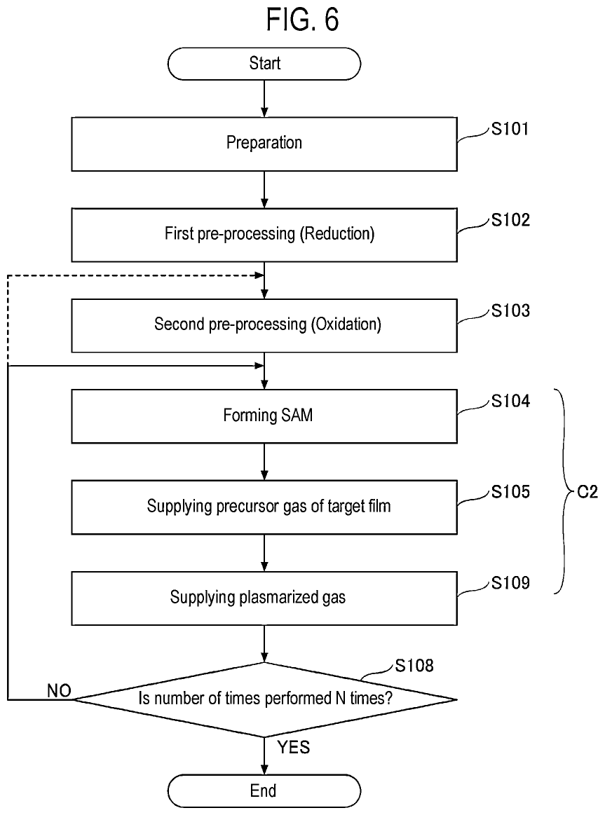

Next, a modification of FIG. 1 will be described with reference to FIG. 6. Hereinafter, differences will be described. A film forming method of the present modification has step S109 instead of steps S106 to S107. Step S109 includes forming the target film 18 and removing the SAM 17 by supplying a reaction gas, which reacts with the precursor gas 18A, in a plasma state to the substrate surface 1a after step S105 (supplying the precursor gas). Formation of the target film 18 and removal of the SAM 17 are performed simultaneously. Therefore, throughput can be improved.

In step S109, at least one selected from the group consisting of, for example, H₂ gas, NH₃ gas, and N₂ gas is used as the reaction gas. When H₂ gas is used alone, formation of a metal film or a semiconductor film, which is the target film 18, and removal of the SAM 17 are performed simultaneously. When NH₃ gas or N₂ gas is used, formation of a nitride film, which is the target film 18, and removal of the SAM 17 are performed simultaneously. The plasmarized reaction gas excites the SAM 17 to decompose and remove the SAM 17.

When the SAM 17 contains fluorine and carbon, by the excitation of the SAM 17, active species containing fluorine and carbon are generated. The active species generated from the SAM 17 react with the precursor gas 18A adsorbed to the SAM 17 to remove the precursor gas 18A from the surface of the conductive film 12. Since the active species are generated in the vicinity of the SAM 17, the precursor gas 18A remains as being adsorbed on the surface of the insulating film 11, and the remaining precursor gas 18A reacts with the reactive gas to selectively form the target film 18 on the surface of the insulating film 11.

Step S108 in FIG. 6 includes checking whether a second cycle C2 has been performed a set number of times (N times). The second cycle C1 includes step S104 (forming the SAM), step S105 (supplying the precursor gas), and step S109 (supplying the plasmarized reaction gas) once each. The second cycle C2 may also include step S103 (oxidizing the conductive film).

The second cycle C2 is repeatedly performed multiple times, for example, in the same processing container. The second cycle C1 is repeatedly performed multiple times by supplying various gases in a desired order into the same processing container. Between adjacent steps, there may be a step of discharging the various gases remaining in the processing container by supplying an inert gas such as argon gas into the processing container.

According to the present modification, the second cycle C2 is repeatedly performed multiple times. The second cycle C2 includes step S104 (forming the SAM), step S105 (supplying the precursor gas), and step S109 (supplying the plasmarized reaction gas) once each. While depositing the target film 18 little by little, the precursor gas 18A adsorbed to the SAM 17 can be removed before the nucleus 18B grows.

Accordingly, even when the blocking performance of the SAM 17 is insufficient, the target film 18 can be selectively formed in a desired region. This effect is noticeably achieved when the conductive film 12 is a Ru film. The reason is because when the conductive film 12 is a Ru film, compared to the case in which the conductive film 12 is a Cu film, the density of the SAM 17 formed on the conductive film 12 easily decreases and the blocking performance of the SAM 17 easily decreases.

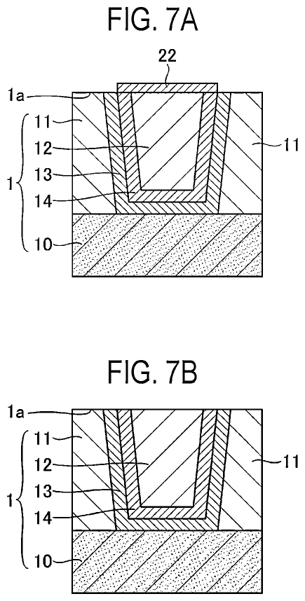

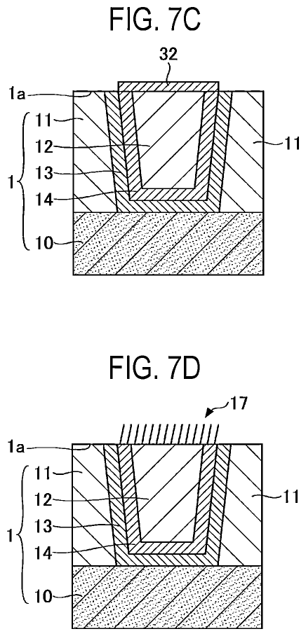

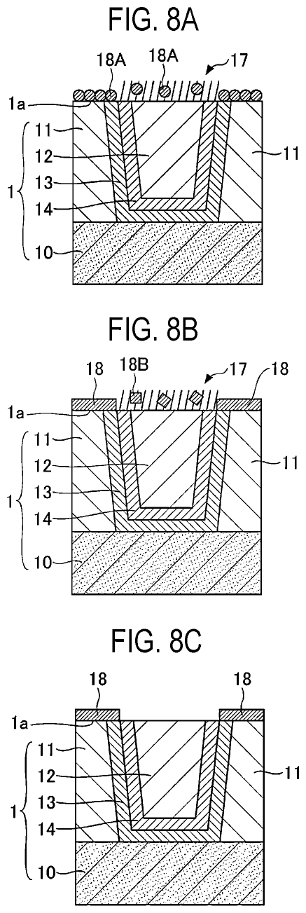

Next, a case in which the substrate 1 according to the first modification is processed by the method of FIG. 1 will be described with reference to FIGS. 7A to 8C. The substrate 1 illustrated in FIG. 7A may be processed by the method of FIG. 5 or 6. Hereinafter, differences will mainly be described.

As illustrated in FIG. 7A, the substrate 1 may have a liner film 14 on the substrate surface 1a, in addition to the insulating film 11, the conductive film 12, and the barrier film 13. The liner film 14 is formed between the conductive film 12 and the barrier film 13. The liner film 14 is formed on the barrier film 13 and assists formation of the conductive film 12. The conductive film 12 is formed on the liner film 14. The liner film 14 is not particularly limited and is, for example, a Co film or a Ru film.

Table 2 summarizes a specific example of the insulating film 11, the conductive film 12, the barrier film 13, and the liner film 14.

TABLE 2

| Insulating Film | Conductive Film | Barrier Film | Liner Film |
|---|---|---|---|
| SiO Film | Cu Film | TaN Film | Co Film |
| SiN Film | | TiN Film | Ru Film |
| SiOC Film | | | |
| SiON Film | | | |
| SiOCN Film | | | |
| SiCN Film | | | |

A combination of the insulating film 11, the conductive film 12, the barrier film 13, and the liner film 14 is not particularly limited.

Step S102 according to the present modification includes removing the contaminant 22 (see FIG. 7A) as illustrated in FIG. 7B. The contaminant 22 is present, for example, on the surface of the conductive film 12 and the surface of the liner film 14. The surface of the conductive film 12 and the surface of the liner film 14 are exposed by step S102.

Step S103 according to the present modification includes forming the oxide film 32 by oxidizing the surface of the conductive film 12 and the surface of the liner film 14, as illustrated in FIG. 7C. Therefore, a dense SAM 17 can be formed on the surface of the conductive film 12 and the surface of the liner film 14 in step S104 described below.

Step S104 according to the present modification includes selectively forming the SAM 17 on the surface of the conductive film 12 and the surface of the liner film 14 with respect to the surface of the insulating film 11, as illustrated in FIG. 7D. The SAM 17 is not formed on the surface of the insulating film 11 and is hardly formed even on the surface of the barrier film 13.

Steps S105 and S106 according to the present modification includes forming the target film 18 on the surface of the insulating film 11 while inhibiting the target film 18 from being formed on the surface of the conductive film 12 and the surface of the liner film 14 by using the SAM 17, as illustrated in FIGS. 8A and 8B. Further, the blocking performance of the SAM 17 is not perfect, and thus the nucleus 18B of the target film 18 may be deposited on the SAM 17.

Even in the present modified example, as in the embodiment described above, the nucleus 18B of the target film 18 deposited on the SAM 17 can be removed before the nucleus 18B grows by performing step S107, as illustrated in FIG. 8C.

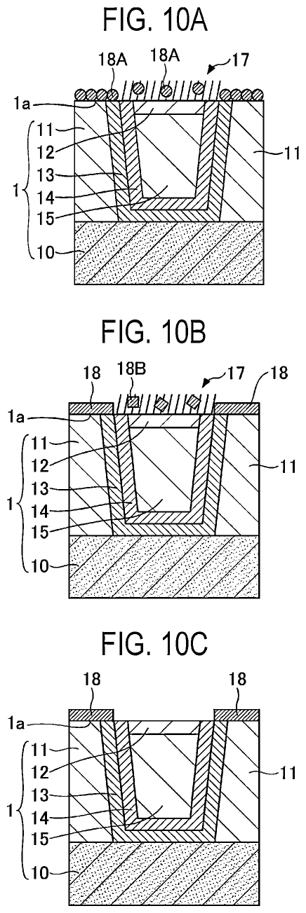

Next, a case in which the substrate 1 according to a second modification is processed by the method of FIG. 1 will be described with reference to FIGS. 9A to 10C. The substrate 1 illustrated in FIG. 9A may be processed by the method of FIG. 5 or 6. Hereinafter, differences will mainly be described.

As illustrated in FIG. 9A, in the substrate 1, the conductive film 12 may be a cap film. That is, as illustrated in FIG. 9A, a second conductive film 15 may be filled in the recess of the insulating film 11, and the conductive film 12 may cover the second conductive film 15. The second conductive film 15 is formed of a metal different from that of the conductive film 12.

Table 3 summarizes a specific example of the conductive film (cap film) 12, the barrier film 13, the liner film 14, and the second conductive film 15.

TABLE 3

| | Conductive | | | Second |
|---|---|---|---|---|
| Insulating | Film | Barrier | Liner | Conductive |
| Film | (Cap Film) | Film | Film | Film |
| SiO Film | Co Film | TaN Film | Co Film | Cu Film |
| SiN Film | Ru Film | TiN Film | Ru Film | |
| SiOC Film | | | | |
| SiON Film | | | | |
| SiOCN Film | | | | |
| SiCN Film | | | | |

In addition, a combination of the insulating film 11, the conductive film 12, the barrier film 13, the liner film 14, and the second conductive film 15 is not particularly limited.

Steps S102 to S107 according to the present modification (see FIGS. 9B to 9D and FIGS. 10A to 10C) are performed in the same manner as steps S102 to S107 according to the first modification (see FIGS. 7B to 7D and FIGS. 8A to 8C).

In addition, in the embodiment, the first modification, and the second modification, the insulating film 11 corresponds to a first film and the conductive film 12 corresponds to a second film, but a combination of the first film and the second film is not particularly limited.

Table 4 shows candidates of a combination of the first film, the second film, and the target film 18 when the precursor of the SAM 17 is a thiol-based compound.

TABLE 4

| SAM | First Film | Second Film | Target Film |
|---|---|---|---|
| Thiol-based | SiN Film | Cu Film | AlO Film |
| | SiO Film | TaN Film | SiO Film |
| | SiOC Film | TiN Film | SiN Film |
| | SiON Film | Co Film | ZrO Film |
| | SiOCN Film | Ru Film | HfO Film |
| | SiCN Film | Au Film | |
| | Spin-On Carbon Film | | |

The candidates listed in Table 4 can be used in any combination. The first film may be an insulating film, the second film may be a conductive film, and the target film 18 formed on the surface of the first film may be an insulating film.

Table 5 shows candidates of a combination of the first film, the second film, and the target film 18 when the precursor of the SAM 17 is a phosphonic acid-based compound.

TABLE 5

| SAM | First Film | Second Film | Target Film |
|---|---|---|---|
| Phosphonic | SiN Film | Cu Film | AlO Film |
| acid-based | SiO Film | TaN Film | SiO Film |
| | SiOC Film | TiN Film | SiN Film |
| | SiON Film | Co Film | ZrO Film |
| | SiOCN Film | | HfO Film |
| | SiCN Film | | |
| | Spin-On Carbon Film | | |

The candidates listed in Table 5 are used in any combination. The first film may be an insulating film, the second film may be a conductive film, and the target film 18 formed on the surface of the first film may be an insulating film.

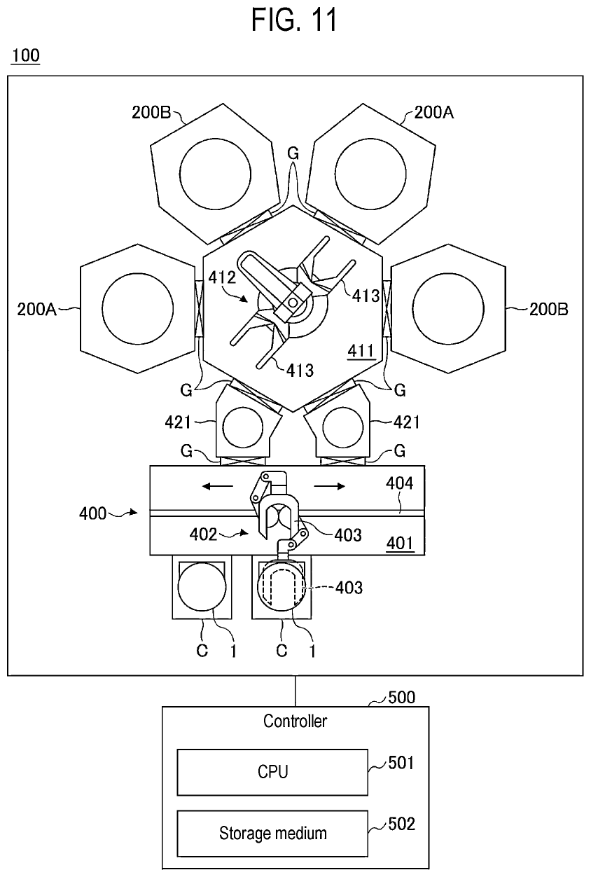

Next, a film forming apparatus 100 for performing the above-described film forming method will be described with reference to FIG. 11. As illustrated in FIG. 11, the film forming apparatus 100 has first processors 200A, second processors 200B, and a controller 500. The first processors 200A perform steps S102 and S103 in FIG. 1, 5, or 6. The second processors 200B perform steps S104 to S107 (first cycle C1) in FIG. 1 or FIG. 5, or steps S104, S105, and S109 (second cycle C2) in FIG. 6. The first processors 200A and the second processors 200B have the same structure. Therefore, it is also possible to perform, using the first processors 200A only, all of steps S102 to S107 in FIG. 1 or FIG. 5 or all of steps S102 to S105, and S109 in FIG. 6. Alternatively, the first processors 200A and the second processors 200B may have different structures. A transferer 400 transfers the substrate 1 to the first processors 200A and the second processors 200B. The controller 500 controls the first processors 200A, the second processors 200B, and the transferer 400.

The transferer 400 has a first transfer chamber 401 and a first transfer mechanism 402. An internal atmosphere of the first transfer chamber 401 is atmospheric atmosphere. The first transfer mechanism 402 is provided inside the first transport chamber 401. The first transfer mechanism 402 includes an arm 403 that holds the substrate 1 and travels along a rail 404. The rail 404 extends in an arrangement direction of carriers C.

In addition, the transferer 400 has a second transfer chamber 411 and a second transfer mechanism 412. An internal atmosphere of the second transport chamber 411 is a vacuum atmosphere. The second transfer mechanism 412 is provided inside the second transfer chamber 411. The second transfer mechanism 412 includes an arm 413 that holds the substrate 1. The arm 413 is arranged to be movable in a vertical direction and a horizontal direction and rotatable around a vertical axis. The first processors 200A and the second processors 200B are connected to the second transfer chamber 411 via different gate valves G.

Further, the transferer 400 has load lock chambers 421 between the first transfer chamber 401 and the second transfer chamber 411. Internal atmospheres of the load lock chambers 421 are switched between a vacuum atmosphere and atmospheric atmosphere by a pressure regulating mechanism which is not illustrated. Therefore, an interior of the second transfer chamber 411 can always be maintained in the vacuum atmosphere. In addition, it is possible to suppress a gas from flowing into the second transfer chamber 411 from the first transfer chamber 401. Gate valves G are provided between the first transfer chamber 401 and the load lock chambers 421 and between the second transfer chamber 411 and the load lock chambers 421.

The controller 500 is, for example, a computer and has a central processing unit (CPU) 501 and a storage medium 502 such as a memory. The storage medium 502 stores a program for controlling various processes executed in the film forming apparatus 100. The controller 500 controls operations of the film forming apparatus 100 by causing the CPU 501 to execute the program stored in the storage medium 502. The controller 500 controls the first processors 200A, the second processors 200B, and the transferer 400 to perform the film forming method.

Next, operations of the film forming apparatus 100 will be described. First, the first transfer mechanism 402 takes the substrate 1 out of the carrier C, transfers the taken-out substrate 1 to the load lock chamber 421, and is then retracted from the load lock chamber 421. The internal atmosphere of the load lock chamber 421 is then switched from atmospheric atmosphere to the vacuum atmosphere. Thereafter, the second transfer mechanism 412 takes the substrate 1 out of the load lock chamber 421 and transfers the taken-out substrate 1 to the first processor 200A.

Next, the first processor 200A performs steps S102 and S103 in FIG. 1, 5, or 6. Thereafter, the second transfer mechanism 412 takes the substrate 1 out of the first processor 200A and transfers the taken-out substrate 1 to the second processor 200B. During this time, an ambient atmosphere of the substrate 1 can be maintained to the vacuum atmosphere.

Next, the second processor 200B performs the first cycle C1 in FIG. 1 or FIG. 5 or the second cycle C2 in FIG. 6. Subsequently, the controller 500 checks whether the first cycle C1 or the second cycle C2 has been performed a set number of times (N times) (step S108). When the number of times of performing the first cycle C1 or the second cycle C2 has not reached the set number (N times), the second processor 200B performs the first cycle C1 or the second cycle C2 again. The first cycle C1 or the second cycle C2 is repeatedly performed multiple times in the same processing container.

On the other hand, when the number of times of performing the first cycle C1 has reached the set number of times (N times), the second transfer mechanism 412 takes the substrate 1 out of the second processor 200B, transfers the taken-out substrate 1 to the load lock chamber 421, and is then retracted from the load lock chamber 421. The internal atmosphere of the load lock chamber 421 is then switched from the vacuum atmosphere to atmospheric atmosphere. Thereafter, the first transfer mechanism 402 takes the substrate 1 out of the load lock chamber 421 and accommodates the taken-out substrate 1 in the carrier C. Then, processing of the substrate 1 ends.

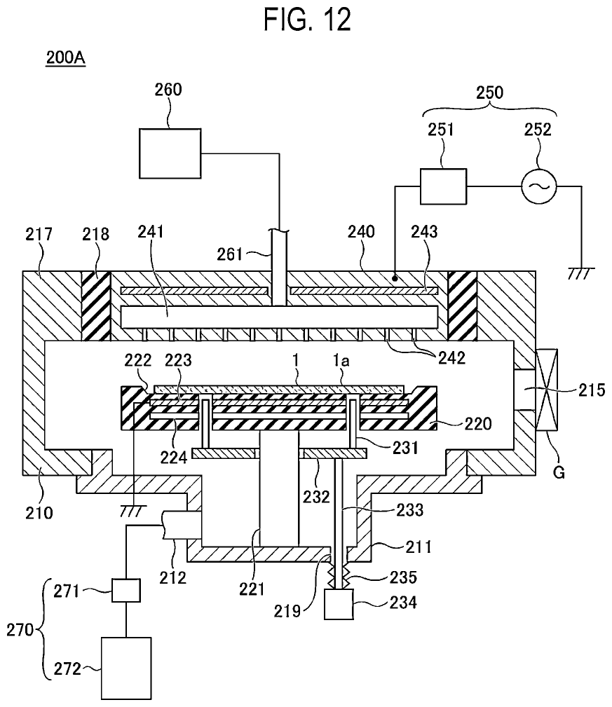

Next, the first processor 200A will be described with reference to FIG. 12. The second processor 200B is configured in the same manner as the first processor 200A, and therefore, illustration and description thereof will be omitted.

The first processor 200A includes a substantially cylindrical and airtight processing container 210. An exhaust chamber 211 is provided at a center portion of a bottom wall of the processing container 210. The exhaust chamber 211 has, for example, a substantially cylindrical shape that protrudes downward. An exhaust pipe 212 is connected to the exhaust chamber 211, for example, on a side surface of the exhaust chamber 211.

An exhaust source 272 is connected to the exhaust pipe 212 via a pressure controller 271. The pressure controller 271 includes, for example, a pressure regulating valve such as a butterfly valve. The exhaust pipe 212 is configured to depressurize an interior of the processing container 210 by the exhaust source 272. The pressure controller 271 and the exhaust source 272 constitute a gas discharge mechanism 270 that discharges a gas in the processing container 210.

A transfer port 215 is provided on a side surface of the processing container 210. The transfer port 215 is opened and closed by a gate valve G. The substrate 1 is loaded and unloaded between the inside of the processing container 210 and the second transfer chamber 411 (see FIG. 11) via the transfer port 215.

A stage 220, which is a holder for holding the substrate 1, is provided inside the processing container 210. The stage 220 holds the substrate 1 horizontally, with the substrate surface 1a facing upward. The stage 220 is formed in a substantially circular shape in a plan view and is supported by a support 221. A substantially circular recess 222 is formed on a front surface of the stage 220 to place the substrate 1 having a diameter of, for example, 300 mm thereon. The recess 222 has an inner diameter slightly larger than the diameter of the substrate 1. A depth of the recess 222 is substantially the same as, for example, a thickness of the substrate 1. The stage 220 is made of, for example, a ceramic material such as aluminum nitride (AlN). In addition, the stage 220 may be made of a metallic material such as nickel (Ni). In addition, instead of the recess 222, a guide ring that guides the substrate 1 may be provided at a peripheral edge of the front surface of the stage 220.

In the stage 220, a grounded lower electrode 223, for example, is buried. A heating mechanism 224 is embedded below the lower electrode 223. The heating mechanism 224 heats the substrate 1 placed on the stage 220 to a set temperature by being fed with power from a power supply (not illustrated) based on a control signal from the controller 500 (see FIG. 11). When the entire stage 220 is made of a metal, since the entire stage 220 functions as a lower electrode, the lower electrode 223 may not be buried in the stage 220. A plurality of (e.g., three) lifting pins 231 for holding the substrate 1 placed on the stage 220 to raise and lower the substrate 1 is provided in the stage 200. A material of the lifting pins 231 may be, for example, ceramic such as alumina (Al₂O₃), or quartz. Lower ends of the lifting pins 231 are attached to a support plate 232. The support plate 232 is connected to a lifting mechanism 234 provided outside the processing container 210 via a lifting shaft 233.

The lifting mechanism 234 is installed, for example, below the exhaust chamber 211. A bellows 235 is provided between an opening 219 for the lifting shaft 233, which is formed in a lower surface of the exhaust chamber 211, and the lifting mechanism 234. The support plate 232 may be shaped to be raised and lowered without interfering with the support 221 of the stage 220. The lifting pins 231 are configured to move vertically between above the front surface of the stage 220 and below the front surface of the stage 220 by the lifting mechanism 234.

A gas supply 240 is provided in a ceiling wall 217 of the processing container 210 via an insulator 218. The gas supply 240 constitutes an upper electrode and faces the lower electrode 223. A radio-frequency power supply 252 is connected to the gas supply 240 via a matcher 251. By supplying radio-frequency power of 400 kHz to 40 MHz from the radio-frequency power supply 252 to the upper electrode (gas supply 240), a radio-frequency electric field is generated between the upper electrode (gas supply 240) and the lower electrode 223 to generate capacitively coupled plasma. A plasma generator 250 that generates the plasma includes the matcher 251 and the radio-frequency power supply 252. The plasma generator 250 may be a plasma generator that generates other plasma, such as inductively coupled plasma, without being limited to the capacitively coupled plasma. In a process without generating plasma, it is not necessary that the gas supply 240 constitutes the upper electrode, and the lower electrode 223 is also unnecessary.

The gas supply 240 includes a hollow gas supply chamber 241. A plurality of holes 242 for dispersedly supplying a process gas into the processing container 210 is disposed, for example, uniformly, on a lower surface of the gas supply chamber 241. In the gas supply 240, a heating mechanism 243 is buried, for example, above the gas supply chamber 241. The heating mechanism 243 is heated to a set temperature by being fed with power from a power supply (not illustrated) based on a control signal from the controller 500.

A gas supply mechanism 260 is connected to the gas supply chamber 241 via a gas supply path 261. The gas supply mechanism 260 supplies a gas used in at least one of steps S102 to S107 in FIG. 1 or FIG. 5, or a gas used in at least one of steps S102 to S105 and S109 in FIG. 6, to the gas supply chamber 241 via the gas supply path 261. Although not illustrated, the gas supply mechanism 260 includes an individual pipe for each gas type, an on-off valve provided in the individual pipe, and a flow rate controller provided in the individual pipe. When the individual pipe is opened by the on-off valve, the gas is supplied from a source to the gas supply path 261. A supply amount of the gas is controlled by the flow rate controller. On the other hand, when the individual pipe is closed by the on-off valve, the supply of the gas from the source to the gas supply path 261 is stopped.

While the embodiments of the film forming method and the film forming apparatus according to the present disclosure have been described, the present disclosure is not limited to the above-described embodiments. Various changes, modifications, substitutions, additions, deletions, and combinations are possible within the scope of the claims. These naturally fall within the technical scope of the present disclosure.

This application claims priority based on Japanese Patent Application No. 2022-042331 filed on Mar. 17, 2022, and the disclosure of Japanese Patent Application No. 2022-042331 is incorporated into this application in its entirety.

### EXPLANATION OF REFERENCE NUMERALS

1: substrate, 1a: substrate surface, 11: insulating film (first film), 12: conductive film (second film), 17: self-assembled monolayer (SAM), 18: target film

1-10. (canceled)

11. A film forming method, comprising:
(A) preparing a substrate having a first film and a second film formed of a material different from a material of the first film in different regions of a surface of the substrate;
(B) selectively forming a fluorine-containing self-assembled monolayer, which inhibits formation of a target film, on a surface of the second film with respect to a surface of the first film;
(C) after (B), supplying a precursor gas of the target film to the surface of the substrate;
(D) after (C), selectively forming the target film on the surface of the first film with respect to the surface of the second film, by supplying a reaction gas that reacts with the precursor gas to the surface of the substrate; and
(E) after (C) and before or after (D), removing the self-assembled monolayer by supplying a plasmarized gas to the surface of the substrate,
wherein a first cycle including (B), (C), (D), and (E) once each is repeatedly performed multiple times.

12. The film forming method of claim 11, wherein a film thickness of the target film formed on the surface of the first film by performing the first cycle once is equal to or less than 1 nm.

13. The film forming method of claim 11, wherein (E) includes supplying at least one selected from the group consisting of H₂ gas, NH₃ gas, N₂ gas, and Ar gas in a plasma state to the surface of the substrate.

14. The film forming method of claim 11, wherein when (E) is performed before (D), (D) includes supplying the reaction gas, which is plasmarized, to the surface of the substrate.

15. The film forming method of claim 11, wherein one of the first film and the second film is an insulating film and the other one is a conductive film.

16. The film forming method of claim 11, wherein a thiol-based compound, an organic silane-based compound, a phosphonic acid-based compound, or an isocyanate-based compound is used as a precursor of the self-assembled monolayer.

17. A film forming method, comprising:
(A) preparing a substrate having a first film and a second film formed of a material different from a material of the first film in different regions of a surface of the substrate;
(B) selectively forming a fluorine-containing self-assembled monolayer, which inhibits formation of a target film, on a surface of the second film with respect to a surface of the first film;
(C) after (B), supplying a precursor gas of the target film to the surface of the substrate; and
(F) after (C), forming the target film and removing the self-assembled monolayer, by supplying a reaction gas, which reacts with the precursor gas, in a plasma state to the surface of the substrate,
wherein a second cycle including (B), (C), and (F) once each is repeatedly performed multiple times.

18. The film forming method of claim 17, wherein a film thickness of the target film formed on the surface of the first film by performing the second cycle once is equal to or less than 1 nm.

19. The film forming method of claim 17, wherein (F) includes supplying, as the reaction gas, at least one selected from the group consisting of H₂ gas, NH₃ gas, and N₂ gas in a plasma state to the surface of the substrate.

20. The film forming method of claim 17, wherein one of the first film and the second film is an insulating film and the other one is a conductive film.

21. The film forming method of claim 17, wherein a thiol-based compound, an organic silane-based compound, a phosphonic acid-based compound, or an isocyanate-based compound is used as a precursor of the self-assembled monolayer.

22. A film forming apparatus, comprising:
a processing container;
a holder configured to hold the substrate inside the processing container;
a gas supply mechanism configured to supply a gas to an interior of the processing container;
a gas discharge mechanism configured to discharge a gas from the interior of the processing container;
a transfer mechanism configured to load and unload the substrate with respect to the processing container; and
a controller configured to control the gas supply mechanism, the gas discharge mechanism, and the transfer mechanism to perform the film forming method of claim 11.

23. A film forming apparatus, comprising:
a processing container;
a holder configured to hold the substrate inside the processing container;
a gas supply mechanism configured to supply a gas to an interior of the processing container;
a gas discharge mechanism configured to discharge a gas from the interior of the processing container;
a transfer mechanism configured to load and unload the substrate with respect to the processing container; and
a controller configured to control the gas supply mechanism, the gas discharge mechanism, and the transfer mechanism to perform the film forming method of claim 17.
